(19) United States
(12) Patent Application Publication
(10) Pub. No.: US 2006/0073675 A1
(43) Pub. Date: Apr. 6, 2006

(54) Semiconductor device and method of manufacturing thereof

(76) Inventor: Tomoyoshi Yamamura, Sakata (JP)

Correspondence Address: HARNESS, DICKEY & PIERCE, P.L.C., P.O. BOX 828, BLOOMFIELD HILLS, MI, 48303, US

(21) Appl. No.: 11/232,337

(22) Filed: Sep. 21, 2005

(30) Foreign Application Priority Data
Oct. 5, 2004 (JP) 2004-292209

(51) Int. Cl. H01L 21/30

(52) U.S. Cl. 438/458

(57) ABSTRACT

A method of manufacturing a semiconductor device, comprises; fixing a plurality of semiconductor substrates to a surface of a wiring substrate in which a perforated line, a grooved portion or grooved portion like the a perforated line is formed in advance; splitting the wiring substrate into a plurality of pieces by breaking the wiring substrate along the perforated line, a grooved portion or grooved portion like the a perforated line. A semiconductor device comprises; a semiconductor substrate; a wiring substrate where the semiconductor substrate is fixed and coupled; and at least one side of the wiring substrate which is formed by breaking the wiring substrate along a perforated line, a grooved portion or grooved portion like the a perforated line.

### BACKGROUND

1. Technical Field

The present invention is related to a semiconductor device and a method of manufacturing thereof. More particularly, it is related to a semiconductor device and a method of manufacturing thereof, by which a wiring substrate is split into a plurality of pieces without using a blade.

2. Related Art

FIG. 8 is a perspective view for conventionally manufacturing a semiconductor device. A semiconductor device manufactured by this method comprises a semiconductor substrate 101 fixed on a wiring substrate 102.

Firstly, the semiconductor substrate 101 and the wiring substrate 102 are prepared. Wirings are installed on the surface of the wiring substrate in advance. The semiconductor substrate 101 is provided with a semiconductor element such as a transistor( not shown), a wiring layer (not shown) and a pad(not shown) in advance. A semiconductor element is coupled to a pad via a wiring layer. Further, a gold bump (not shown) is formed on a pad.

Next, a plurality of semiconductor substrates 101 are fixed onto the wiring substrate 102 with using anisotropic conductive resin (not shown.) Here, a gold bump of the semiconductor substrate 101 is coupled to the wiring of the wiring substrate 102 via anisotropic conductive resin. Then, a solder ball for connecting outside (not shown) is formed on the back side of the wiring substrate thereafter. Then, the wiring substrate 102 is split into plural pieces by using a blade 103.

When the wiring substrate is split by using a blade, however, there is a case when chipped waste is left at the cut surface. Such chipped waste should be removed after cutting the substrate in order to avoid a problem in a latter process, causing necessity of additional job.

Further, it is often necessary to replace a used blade with new one in order to avoid chipped waste left when a blade is abrade. Accordingly this problem causes high cost in manufacturing a semiconductor device.

### SUMMARY

In view of the above situation, the present invention is intended to provide a semiconductor device and a method of manufacturing it by which a wiring substrate is split into a plurality of pieces without using a blade.

According to a first aspect of the invention, a method of semiconductor device comprises: fixing a plurality of semiconductor substrates to a surface of a wiring substrate in which a perforated line is formed in advance; splitting the wiring substrate into a plurality of pieces by breaking the wiring substrate along the perforated line.

According to this method, a perforated line is formed on the wiring substrate in advance splitting the wiring substrate into plurality of pieces by breaking the wiring substrate along the perforated line. Therefore, chipped waste is not easily left at the side end of the wiring substrate after splitting thereby. Further, there is no necessity of using a blade, contributing low cost in manufacturing a semiconductor device.

Further other aspect of the invention, a method of semiconductor device comprises; fixing a plurality of semiconductor substrates to a surface of a wiring substrate in which a grooved portion is formed in advance; splitting the wiring substrate into a plurality of pieces by breaking the wiring substrate along the groove.

Further other aspect of the invention, a method of semiconductor device comprises; fixing a plurality of semiconductor substrates to a surface of a wiring substrate in which a grooved portion like a perforated line is formed in advance; splitting the wiring substrate into a plurality of pieces by breaking the wiring substrate along the grooved portion.

According to this method, the wiring substrate is split into plurality of pieces by breaking the wiring substrate along the grooved portion. Therefore, chipped waste is not easily left at the side end of the wiring substrate after splitting thereby. Further, there is no necessity of using a blade, contributing low cost in manufacturing a semiconductor device.

The step of splitting the wiring substrate into a plurality of pieces may include a process of breaking the wiring substrate with bending the wiring substrate along to the grooved portion. Further, the perforated line or the grooved portion may be formed with laser irradiation or etching.

A semiconductor device of the invention comprises: a wiring substrate where the semiconductor substrate is fixed and coupled; at least one side of the wiring substrate is formed by breaking the wiring substrate along a perforated line.

According to other aspect of a semiconductor device of the invention, the semiconductor device comprises; a semiconductor substrate in which a bump is formed; a wiring substrate where the semiconductor substrate is fixed and coupled; at least one side of the wiring substrate is formed by breaking the wiring substrate along a groove.

According to other aspect of a semiconductor device of the invention, the semiconductor device comprises; a semiconductor substrate in which a bump is formed; a wiring substrate where the semiconductor substrate is fixed and coupled; at least one side of the wiring substrate is formed by breaking the wiring substrate along a grooved portion like a perforated line.

The semiconductor device may further comprises a second semiconductor substrate, which is fixed to the semiconductor substrate.

### BRIEF DESCRIPTION OF THE DRAWINGS

The invention will be described with reference to the accompanying drawings, wherein like numbers refer to like elements, and wherein:

FIG. 1 is a side view of a semiconductor device of a first embodiment;

FIG. 2 is a flow chart of the method of manufacturing a semiconductor device;

FIG. 3A is a perspective view of the wiring substrate 2 in the step S2 in FIG. 2; FIG. 3B is a perspective view of the wiring substrate 2 in the step S4 in FIG. 2;

FIG. 4 is a cross section for explaining the step S8 in FIG. 2;

FIG. 5 is a perspective view showing a method for manufacturing a semiconductor device according to a second embodiment of the invention;

FIG. 6 is a perspective view showing a method for manufacturing a semiconductor device according to a third embodiment of the invention;

FIG. 7 is a side view of a semiconductor device according to a fourth embodiment of the invention; and

FIG. 8 is a perspective view for conventionally manufacturing a semiconductor device

### DESCRIPTION OF THE EMBODIMENTS

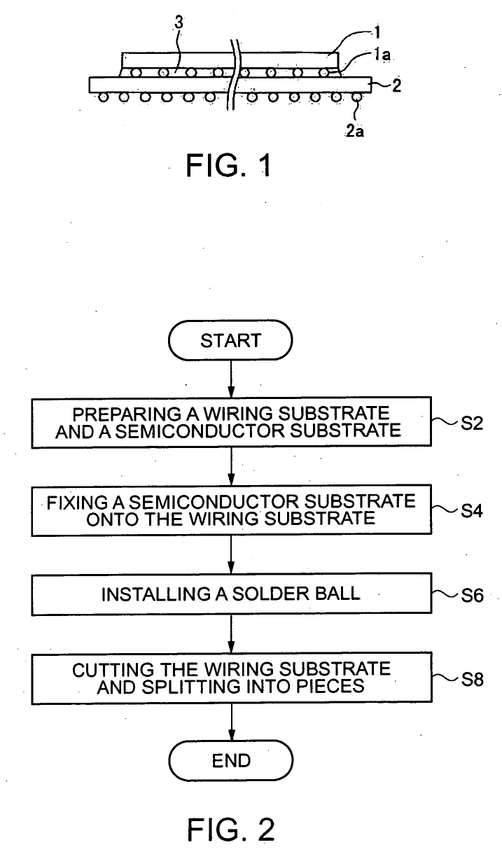

The preferred embodiments of the invention are explained referring with figures. FIG. 1 is a side view of a semiconductor device of a first embodiment. The semiconductor device has a Flip Chip Ball Grid Array (FC-BGA) structure, in which a semiconductor substrate 1 is fixed onto the surface of a wiring substrate 2 via an anisotropic conductive resin 3.

The semiconductor substrate 1 is provided with a plurality of transistors (not shown) and a plurality of wiring layers on them. A transistor is coupled to an aluminum pad, which is exposed on the surface of the wiring layer via a plurality of wiring layers. The aluminum alloy pad I provided with a gold bump 1a thereon, and coupled to the surface of the wiring substrate 2 via the gold bump 1a and the anisotropic conductive resin 3.

The wiring substrate 2 is provided with a multi-layered structure of insulation resin layers (not shown) with copper wiring pattern layers (not shown), which are deposited alternatively. A wiring pattern layer is located on the surface of the wiring substrate 2. Here, the wiring substrate 2 may be provided with a single resin layer and a single wiring layer.

A plurality of solder balls 2a are formed on the back surface of the wiring substrate 2 for an output terminal to outside. The solder balls 2a are coupled to the wiring layers via connecting halls (not shown) installed in a resin layer of the wiring substrate 2.

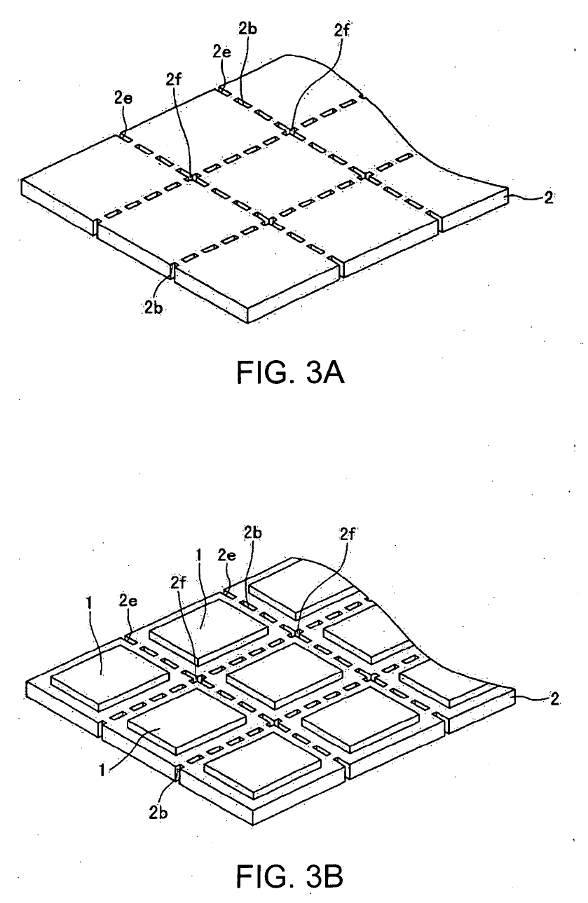

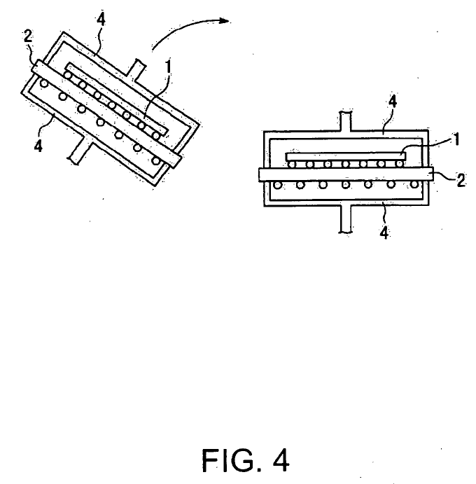

FIG. 2 is a flow chart of a method of manufacturing a semiconductor device shown in FIG. 1. FIG. 3A is a perspective view of the wiring substrate 2 in the step S2 in FIG. 2. FIG. 3B is a perspective view of the wiring substrate 2 in the step S4 in FIG. 2. FIG. 4 is a cross section for explaining the step S8 in FIG. 2.

Firstly, the semiconductor substrate 1 and the wiring substrate 2 are prepared (S2 in FIG. 2.) In this step, the semiconductor substrate is provided with a transistor, a wiring layer, an aluminum alloy pad, and a gold bump 1a. Further, the resin layer and the wiring pattern layer are formed in the wiring substrate 2, but the solder ball 2a is not formed at this stage.

As shown in FIG. 3A, a plurality of pieces of the wiring substrate 2 are connected each other and a perforated line 2b is formed at the boundary of them. The perforated line 2b may be formed by irradiating a laser beam to the wiring substrate 2, for example.

Here, the perforated line 2b may be formed at the same time for forming the wiring substrate 2 by repeating the following process. Firstly a resin layer is formed and a copper thin film is formed thereon. Next, a mask is formed on the copper thin film with a resist pattern and the thin film is etched with using the mask thereafter. The copper thin film is patterned thereby, forming a wiring pattern layer. Next, after removing a mask on the wiring pattern layer, a new mask is formed with a resist pattern, etching a resin layer with using this mask so as to form the perforated line 2b in the resin layer. Then, the mask is removed.

It is preferable that one of the perforated lines 2b is overlapped with the other line (the reference numeral 2f shown in the figure, for example) and/or the end part (the reference numeral 2e shown in the figure, for example) of the wiring substrate 2. Hence, the wiring substrate 2 is easily split like a straight line even at the cross point of the perforated line with the other line or the end portion at the splitting process described below.

Next, the semiconductor substrate 1 is fixed on a predetermined position of the wiring substrate 2 by using an anisotropic conductive resin 3 (S4 of FIG. 2 and FIG. 3.B.) Here, a gold bump 1a of the semiconductor substrate 1 is coupled to the wiring pattern of the wiring substrate 2 via anisotropic conductive resin 3.

Then, a solder ball 2a is installed on the back face of the wiring substrate (S6 of IFG.2.) Next, the wiring substrate 2 is bent along the perforated line 2b with using a cutter 4. Thus, the wiring substrate 2 is cut along the perforated line 2b and split into each of semiconductor substrate pieces (S8 in FIG. 2 and FIG. 4.) Thus, the wiring substrate 2 after splitting is formed so that at least on side of it is cut along the perforated line.

Here, it is preferable that the cutter 4 supports a part in which a solder ball 2a is not installed among the bottom area of the wiring substrate 2 and also supports a part in which a semiconductor substrate is not installed among the upper area of the wiring substrate 2 and bents the wiring substrate 2 under such state. Hence, applying unnecessary power to a solder ball 2a and the semiconductor substrate 1 can be avoided thereby when the wiring substrate 2 is cut.

Thus, the semiconductor device of the embodiment is split into a individual piece by forming the perforated line 2b in the wiring substrate 2 in advance and cutting the wiring substrate 2 along the perforated line 2b. Hence, the wiring substrate 2 can be split into pieces without using a blade. Therefore, a process for removing chipped wastes can be omitted since there is no such waste along the cut section. Further, there is no necessity of using a blade, contributing low cost in manufacturing a semiconductor device.

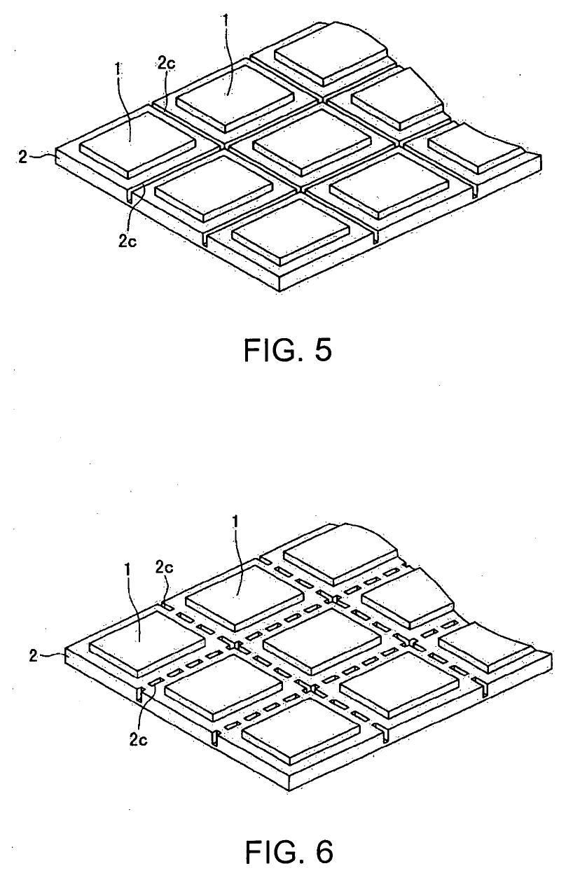

FIG. 5 is a perspective view showing a method for manufacturing a semiconductor device according to a second embodiment of the invention. In this embodiment, a groove 2c is formed instead of the perforated line 2b. Other processes are the same of the embodiment 1. Namely, the semiconductor device is formed by cutting at a least side along the groove 2c. The embodiment has the same effect of the first embodiment.

FIG. 6 is a perspective view showing a method for manufacturing a semiconductor device according to a third embodiment of the invention. In this embodiment, a groove 2c is formed like a perforated line. Other processes are the same of the embodiment 2. Then, a semiconductor device manufactured by the method of according to the embodiment is formed by a process in which at least one side is formed by cutting the groove like a perforated line 2c. The present embodiment has the same effect of the first embodiment.

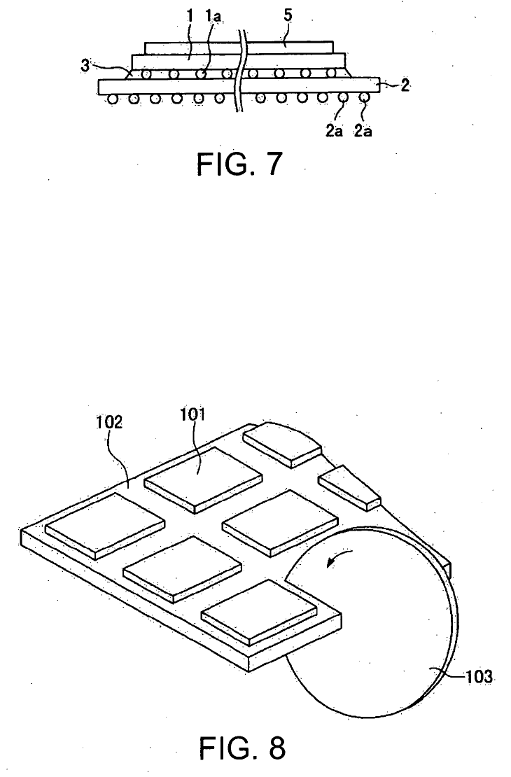

FIG. 7 is a side view of a fourth embodiment of a semiconductor device of the invention. In the embodiment, other semiconductor substrate 5 is installed on the semiconductor substrate 1. A pad (not shown) formed on the semiconductor substrate 5 is coupled to the wring pattern of the wiring substrate 2 via a wiring (not shown) formed on the semiconductor substrate 1. Other structures of the semiconductor device are the same of the first embodiment and the same reference numerals are applied and these explanations are omitted.

The second semiconductor substrate 5 is fixed on the semiconductor substrate 1 after the semiconductor substrate 1 is fixed on the wiring substrate 2 before installing the solder ball 2a on the wiring substrate 2. The pad installed on the semiconductor substrate 5 is coupled to the wiring on the semiconductor substrate 1. The wiring is coupled to the pad of the semiconductor substrate 1. Other structures of the semiconductor device and a method of it are the same of the first embodiment. The present embodiment has the same effect of the first embodiment.

The present invention is not limited to the above-mentioned embodiments and can be applied to various modifications within a spirit of the invention. For example, methods of manufacturing a semiconductor device according to the second and third embodiments can be applied to a method of manufacturing the semiconductor device of the fourth embodiment.

What is claimed is;

1. A method of manufacturing a semiconductor device, comprising;
fixing a plurality of semiconductor substrates to a surface of a wiring substrate in which a perforated line is formed in advance;
splitting the wiring substrate into a plurality of pieces by breaking the wiring substrate along the perforated line.

2. A method of manufacturing a semiconductor device, comprising;
fixing a plurality of semiconductor substrates to a surface of a wiring substrate in which a grooved portion is formed in advance;
splitting the wiring substrate into a plurality of pieces by breaking the wiring substrate along the grooved portion.

3. A method of manufacturing a semiconductor device, comprising;
fixing a plurality of semiconductor substrates to a surface of a wiring substrate in which a groove portion like a perforated line is formed in advance;
splitting the wiring substrate into a plurality of pieces by breaking the wiring substrate along the groove portion like the perforated line.

4. The method of manufacturing a semiconductor device according to claim 1, wherein the step of splitting the wiring substrate into a plurality of pieces includes a process of breaking the wiring substrate with bending the wiring substrate along the perforated line.

5. The method of manufacturing a semiconductor device according to claim 2, wherein the step of splitting the wiring substrate into a plurality of pieces includes a process of breaking the wiring substrate with bending the wiring substrate along the groove portion.

6. The method of manufacturing a semiconductor device according to claim 3, wherein the step of splitting the wiring substrate into a plurality of pieces includes a process of breaking the wiring substrate with bending the wiring substrate along the groove portion like the perforated line.

7. The method of manufacturing a semiconductor device according to claim 1, wherein the perforated line is formed with laser irradiation or etching.

8. The method of manufacturing a semiconductor device according to claim 2, wherein the grooved portion is formed with laser irradiation or etching.

9. The method of manufacturing a semiconductor device according to claim 3, wherein the grooved portion like the perforated line is formed with laser irradiation or etching.
